(19) United States
(12) Patent Application Publication
(10) Pub. No.: US 2012/0170194 A1
(43) Pub. Date: Jul. 5, 2012

(54) MOBILE COMPUTER STAND

(76) Inventors: Charles Lord, Scottsdale, AZ (US); Joseph Elijio Velasquez, Fountain Hills, AZ (US); Jeff Doss, Scottsdale, AZ (US); Troy Sherman, Gilbert, AZ (US)

(21) Appl. No.: 13/309,989

(22) Filed: Dec. 2, 2011

Related U.S. Application Data
(60) Provisional application No. 61/430,092, filed on Jan. 5, 2011.

(51) Int. Cl. G06F 1/16; F16L 3/22; H05K 7/00

(52) U.S. Cl. 361/679.02; 248/371; 248/68.1; 248/121; 248/682

(57) ABSTRACT

A mobile computer stand is provided. The mobile computer stand includes a support portion comprising a base member, a rotatable member operatively coupled to the base member and an axis. The stand further includes a connection member operatively coupled to the support portion, wherein the connection member rotates about the axis in response to rotation of the rotatable member about the axis. Additionally, the connection member is freely rotatable through an entire 360 degrees of rotation in each direction with respect to the support portion.

### CROSS REFERENCE TO RELATED APPLICATION

This application claims priority to U.S. Provisional Patent Application entitled “Mobile Computer Stand,” Ser. No. 61/430,092, filed Jan. 5, 2011, now pending, the disclosures of which are hereby incorporated entirely herein by reference.

### BACKGROUND OF THE INVENTION

1. Technical Field

This invention relates generally to a computer stand and more particularly to a mobile computer stand.

2. State of the Art

Mobile computers are popular for several reasons including the size, the ease of transport, the speed of operation and the convenience. The use of a mobile computer requires supporting the mobile computer and using hands to perform the functions by touching the screen. The screen is equipped with touch capability for user entry and interfacing with the mobile computer. Often times, the mobile computer is supported by the user's lap, hands or a horizontal surface, like a table. This allows the user to use one or two hands to operate the mobile computer and interface with programs and applications installed on the computer.

Additionally, many mobile computers may be connected to external input devices, such as an external keyboard. The keyboard may be used to type various alpha, numeric and symbolic characters on the mobile computer. Other external accessories may be used with mobile computers.

There is a need with mobile computers to provide an apparatus that can function as a stand, wherein the stand is adjustable to place the mobile computer at various angles as defined by a user in order to best view and operate the mobile computer. Further, there is a need to provide a device for carrying the mobile computer and further to secure the mobile computer during transport.

Conventionally, there is not a device that can perform all of these functions. Accordingly, there is a need in the field of mobile computer stands, for an improved mobile computer stand that also functions as a carrying device and a protection device for the mobile computer.

### DISCLOSURE OF THE INVENTION

The present invention relates to a stand for a mobile computer that further functions as a carrying device and a protection device for the mobile computer. Generally, the mobile computer includes stand portion and a connection member.

An aspect includes a mobile computer stand comprising a support portion comprising a base member, a rotatable member operatively coupled to the base member and an axis. The stand further comprises a connection member operatively coupled to the support portion, wherein the connection member rotates about the axis in response to rotation of the rotatable member about the axis.

Another aspect includes a mobile computer stand comprising a support portion comprising a base member, a rotatable member operatively coupled to the base member and an axis. The stand also comprises a connection member removably and operatively coupled to the support portion, wherein the connection member rotates about the axis in response to rotation of the rotatable member about the axis.

Yet another aspect includes a method of using a mobile computer stand, the method comprising releaseably connecting a mobile computer to a connection member of a mobile computer stand; moving the mobile computer stand from a folded position to an unfolded position; supporting a base of the mobile computer stand with a support surface; and rotating the mobile computer to one of a portrait or a landscape position in response to rotating the connection member to one of a portrait or a landscape position.

The foregoing and other features and advantages of the present invention will be apparent from the following more detailed description of the particular embodiments of the invention, as illustrated in the accompanying drawings.

### BRIEF DESCRIPTION OF THE DRAWINGS

FIG. 1 is a perspective view of a mobile computer stand with the support portion in a folded position and a connection member in a landscape position with respect to the support portion.

FIG. 2 is a perspective view of a mobile computer stand with the support portion in a folded position and a connection member in a portrait position with respect to the support portion.

FIG. 3 is a perspective view of a mobile computer stand with the support portion in an unfolded position and a connection member in a landscape position with respect to the support portion.

FIG. 4 is a perspective view of a mobile computer stand with the support portion in an unfolded position and a connection member in a portrait position with respect to the support portion.

FIG. 5 is a side view of a mobile computer stand with a mobile computer coupled to it.

FIG. 6 is a front view of a mobile computer stand with a mobile computer inserted within a protective sleeve.

FIG. 7 is a flow chart of a method of using a mobile computer stand.

### DETAILED DESCRIPTION OF EMBODIMENTS OF THE INVENTION

As discussed above, embodiments of the present invention relate to a stand for a mobile computer that further functions as a carrying device and a protection device for the mobile computer. Generally, the mobile computer includes stand portion and a connection member.

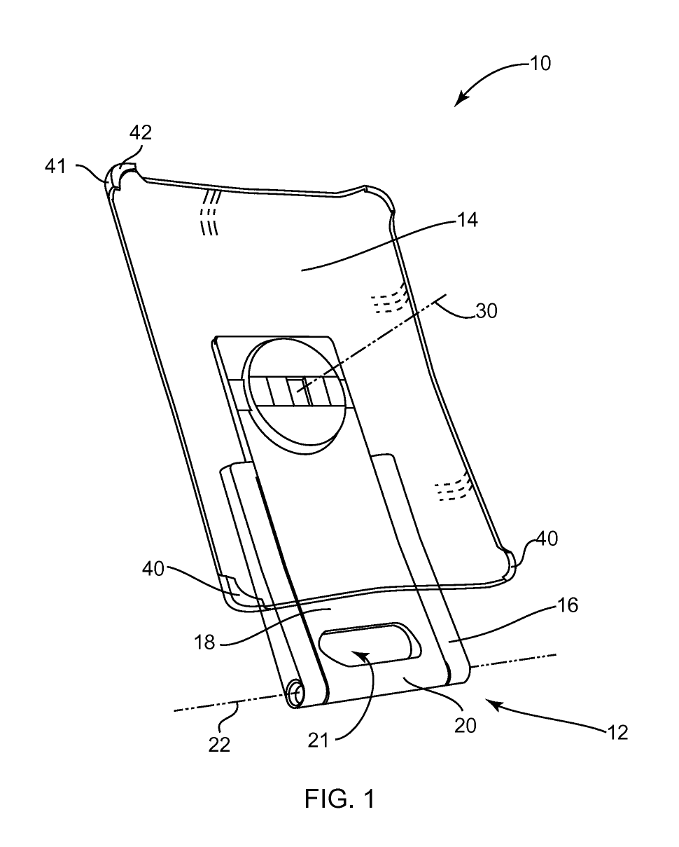

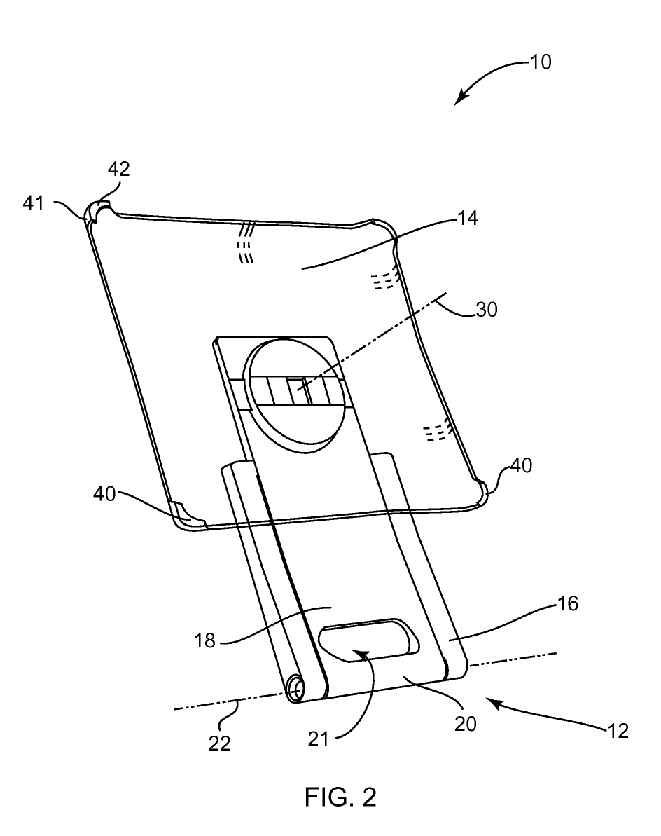

Referring to the drawings, FIGS. 1 and 2 depict a mobile computer stand 10 in a folded position according to embodiments of the invention. The stand 10 comprises a support portion 12 and a connection member 14. The connection member 14 is operatively coupled to the support portion 12. The connection member 14 may be rotatably coupled to a rotatable member 18 of the support portion 12. The connection member 14 includes an axis 30, wherein the connection member 14 is freely rotatable with respect to the support portion 12 about the axis 30, and the support portion 12 is freely rotatable with respect to the connection member 14 about the axis 30. The connection member 14 is freely rotatable through an entire 360 degrees of rotation in each direction about axis 30 and with respect to the support portion 12, such that the connection member 14 can freely rotate about the axis 30 as little, or as much, as desired by the user. Moreover, the connection member 14 can freely rotate about the axis 30 in a complete 360 degree rotation as many times in succession as desired by the user.

Likewise, the support portion 12 is freely rotatable through an entire 360 degrees of rotation in each direction about axis 30 and with respect to the connection member 14, such that the support portion 12 can freely rotate about the axis 30 as little, or as much, as desired by the user. Moreover, the support portion 12 can freely rotate about the axis 30 in a complete 360 degree rotation as many times in succession as desired by the user.

Accordingly, as is common with mobile computers, an accelerometer or multiple accelerometers are located within the mobile computer allowing the screen orientation to respond to rotation of the table computer. Because certain applications operated on the mobile computer are optimally run in either a portrait or a landscape orientation, the connection member 14 is rotatable between a portrait and a landscape position as shown in FIGS. 1 and 2, as well as any angle in between. The mobile computer may be interacted with by the user at any angle.

The connection member 14 includes connectors 40. In this embodiment, the connectors 40 are located on corners of the connection member 14. The connectors 40 engage the mobile computer and removably secure the mobile computer to the connection member 14. The mobile computer may be coupled to the connection member 14 by use of the connectors 40 with a back side of the mobile computer facing the connection member 14. This allows the connection member 14 to retain the mobile computer while still allowing access to the touch screen of the mobile computer. The connectors 40 may include a side portion 41 and a lip portion 42. The side portion 41 engages a portion of a corner of the mobile computer and the lip portion 42 engages a front surface of the mobile computer. This allows the mobile computer to be coupled to the connection member 14 with a back portion of the mobile computer facing the connection member 14 and the connectors 40 removably securing the mobile computer to the connection member 40. The connection member may be formed of a resilient material allowing for bending of the connection member 14, thereby allowing the lip portion 42 of each connector 40 to engages the front surface by enlarging the opening between opposing connectors to a width greater that the width of the mobile computer. The resiliency of the material of the connection member 14 functions to return the connection member 14 to its resting form thereby securing the mobile computer within the connection member 14.

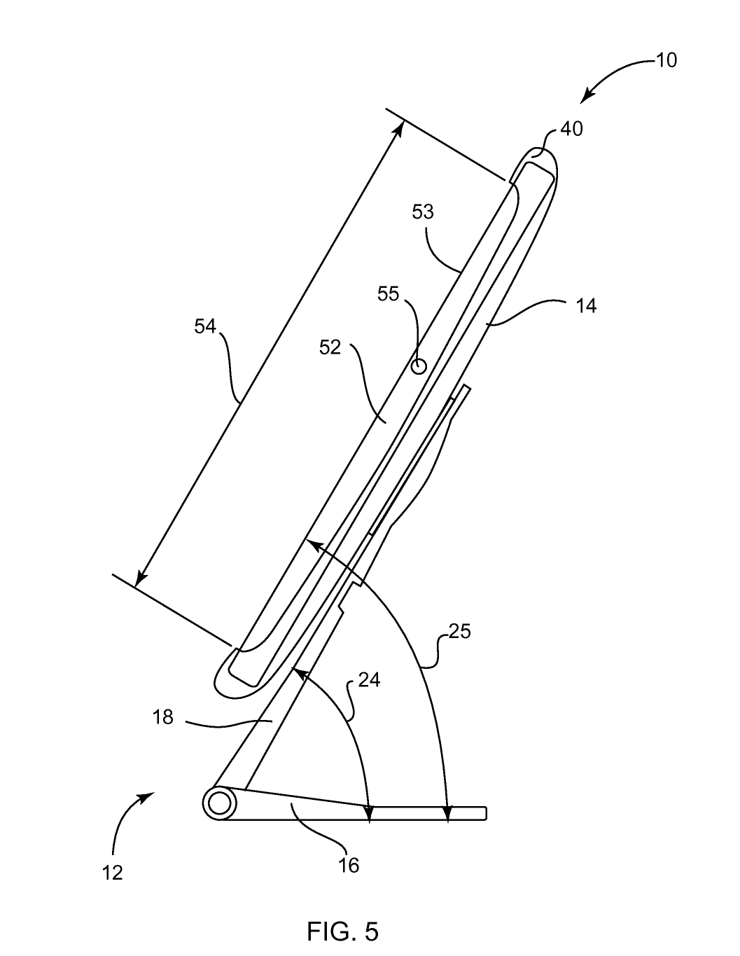

The connectors 40 in particular embodiments and as shown are located at the corners functions to support the mobile computer when it is both in the landscape and portrait positions. Further, locating the connectors at the corners provides spaces 54, as shown in FIG. 5, to allow for connection of accessories and auxiliary components, such as, but not limited to, power cables, cameras, ear phones, AV cables and the like to input and output slots or receivers 55 of the mobile computer 52.

The connectors 40 may be located in different locations and need not be at the corners. The connectors 40 can be located in any location that does not conflict with the port locations of the mobile computer.

The connection member 14 is removably coupled to the support portion 12. This allows the connection portion to further function as a protective member to inhibit scratches, dents and dust on the back surface of the mobile computer. It also allows a user to easily operate the mobile computer in the user's lap.

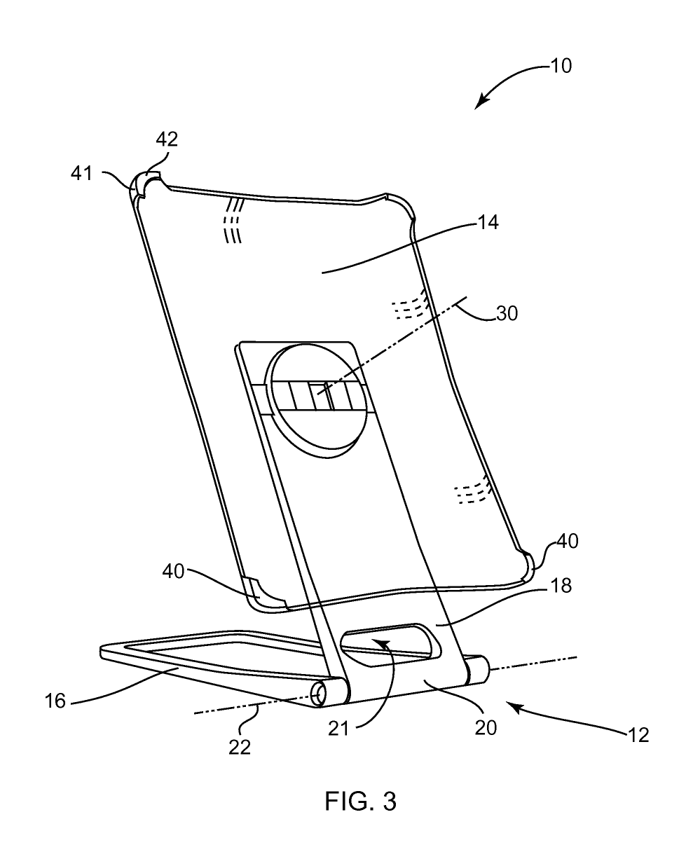

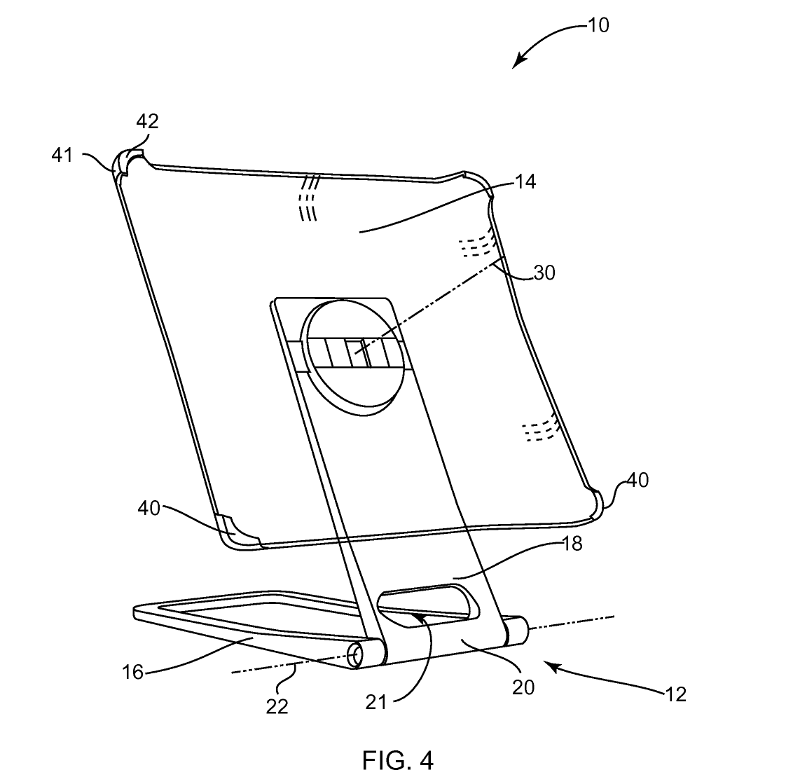

Referring also to FIGS. 3-5, the support portion 12 includes a base 16 and a rotatable member 18. The rotatable member 18 is operatively coupled to the base. For example, the rotatable member 18 may be coupled to the base 16 by use of a hinge, such as, but not limited to, a torque hinge. The support member 12 comprises an axis 22 that extends along the coupled ends of the base 16 and the rotatable member 18. The rotatable member 18 is rotatable with respect to the base 16 about the axis 22, and the base 16 is rotatable with respect to the rotatable member 18 about the axis 22.

The support portion 12 includes an angle 24 defined between the base 16 and the rotatable member 18 of the support portion 12. The angle 24 is defined by rotation of the rotatable member 18 with respect to the base 16. In some embodiments, the angle 24 may be any angle within the range of 0° to 90°. In other embodiments, the angle 24 may be any angle within the range of 0° to 85°, and further other embodiments the angle 24 may be any angle within the range of 0° to 75°. The stand 10 is in a folded position when the angle 24 between the base 16 and the rotatable member 18 is approximately 0°.

Further, connection member 14 is operatively coupled to the rotatable member 18 of the support portion 12, wherein the angle 25 between the base 16 and a front surface 53 of the mobile computer 52 coupled to the connection member 14 is adjusted in response to rotation of the rotatable member 18.

According to some embodiments, the base 16 may be formed in a U-shape substrate and the rotatable member 18 may be formed of a rectangular substrate with an aperture 21 extending through the substrate at one end. An end of rotatable member 18 is rotatable coupled to the open end of the U-shapes base 16. In some embodiments, this may be accomplished by use of a torque hinge, or a friction hinge. In these embodiments the base 16 has apertures through each open end of the U-shape substrate that each corresponds to a recess extending from a side surface near an end of the rotatable member 18 substrate, wherein a hinge is received in one aperture and one recess. In some embodiments, one torque or friction hinge is used. In other embodiments, two torque or friction hinges are used.

While it is shown that the base 16 is U-shaped, other shapes may be used while performing the same function. For example, and without limitation, the shape of the base may be a circular shape, a ring shape, and square shape, a rectangular shape, a triangular shape, an elliptical shape, an oblong shape, a rectilinear shape or other type of shape that can support the rotatable member 18, the connection member and a mobile computer coupled to the connection member 14.

In some embodiments, the aperture 21 extending through the substrate forming the rotatable member forms the handle 20. Accordingly, in these embodiments the handle 20 is formed at the end where the rotatable member 18 is coupled to the base 16.

The support portion 12 may further comprise a lock mechanism, wherein the lock mechanism releaseably secures the rotatable member 18 to the base 16 when the stand 10 is in the folded position. The lock mechanism prevents accidental unfolding of the support portion 12. In this folded position, the support portion 12 further comprises a handle 20. The handle may be defined by an aperture 21 extending through the support portion 12. The handle 20 allows a user to carry the stand 10, and further to carry the stand 10 with a mobile computer coupled therein.

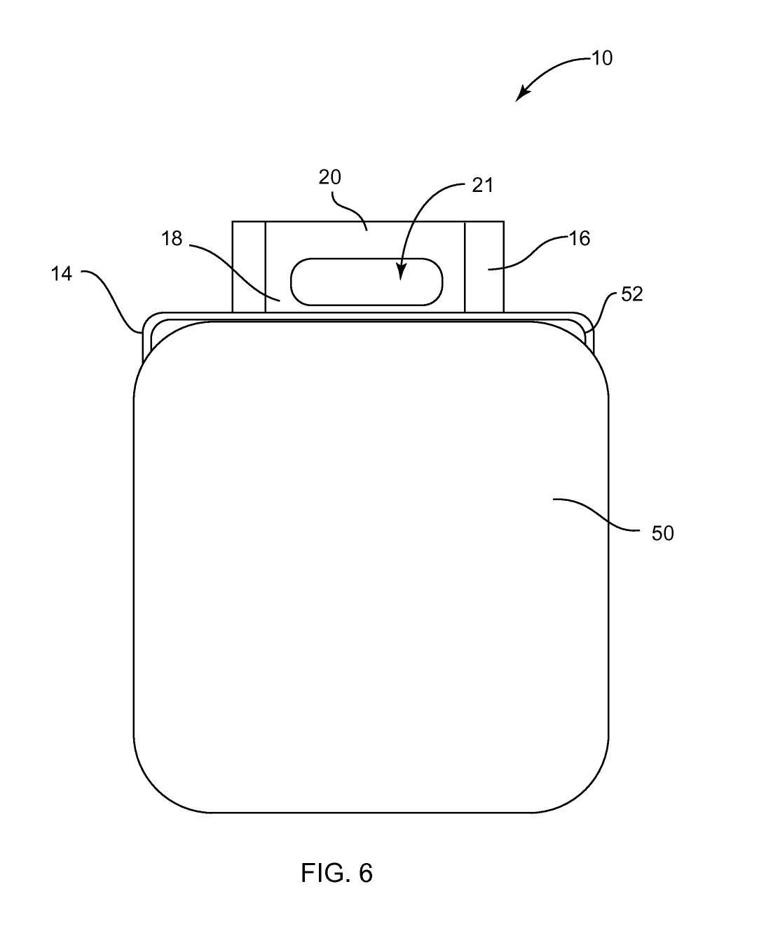

In particular embodiments, as shown in FIG. 6, when the stand 10 is in the folded position, a protective covering or sleeve 50 may receive the mobile computer and the stand, wherein only the handle 20 of the support portion 12 extends from the sleeve 50. The handle may then be used to carry or otherwise transport the mobile computer coupled to the stand 10 while inhibiting damage to the stand 10 and the mobile computer during transport.

The components defining any mobile computer stand 10 may be formed of any of many different types of materials or combinations thereof that can readily be formed into shaped objects provided that the components selected are consistent with the intended operation of a mobile computer stand. For example, the components may be formed of: rubbers (synthetic and/or natural) and/or other like materials; glasses (such as fiberglass) carbon-fiber, aramid-fiber, any combination thereof, and/or other like materials; polymers such as thermoplastics (such as ABS, Fluoropolymers, Polyacetal, Polyamide; Polycarbonate, Polyethylene, Polysulfone, and/or the like), thermosets (such as Epoxy, Phenolic Resin, Polyimide, Polyurethane, Silicone, and/or the like), any combination thereof, and/or other like materials; composites and/or other like materials; metals, such as zinc, magnesium, titanium, copper, iron, steel, carbon steel, alloy steel, tool steel, stainless steel, aluminum, any combination thereof, and/or other like materials; alloys, such as aluminum alloy, titanium alloy, magnesium alloy, copper alloy, any combination thereof, and/or other like materials; any other suitable material; and/or any combination thereof.

Furthermore, the components defining any mobile computer stand may be purchased pre-manufactured or manufactured separately and then assembled together. However, any or all of the components may be manufactured simultaneously and integrally joined with one another. Manufacture of these components separately or simultaneously may involve extrusion, pultrusion, vacuum forming, injection molding, blow molding, resin transfer molding, casting, forging, cold rolling, milling, drilling, reaming, turning, grinding, stamping, cutting, bending, welding, soldering, hardening, riveting, punching, plating, and/or the like. If any of the components are manufactured separately, they may then be coupled with one another in any manner, such as with adhesive, a weld, a fastener (e.g. a bolt, a nut, a screw, a nail, a rivet, a pin, and/or the like), wiring, any combination thereof, and/or the like for example, depending on, among other considerations, the particular material forming the components. Other possible steps might include sand blasting, polishing, powder coating, zinc plating, anodizing, hard anodizing, and/or painting the components for example.

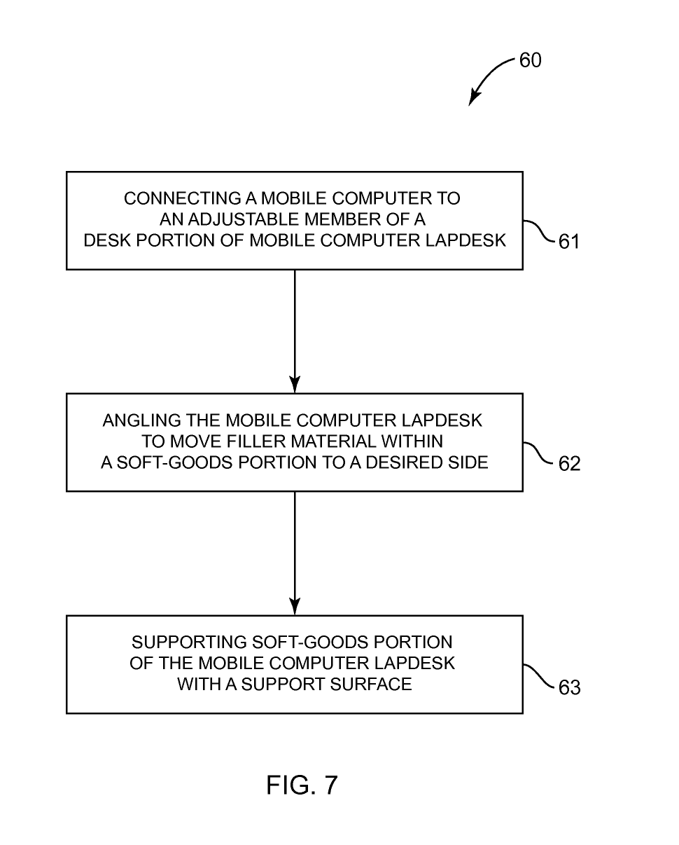

As shown in FIG. 7, embodiments may include a method 60 of using a mobile computer stand. The method 60 comprises releaseably connecting a mobile computer to a connection member of a mobile computer stand (Step 61); moving the mobile computer stand from a folded position to an unfolded position (Step 62); supporting a base of the mobile computer stand with a support surface (Step 63); and rotating the mobile computer to one of a portrait or a landscape position in response to rotating the connection member to one of a portrait or a landscape position (Step 64).

Step 62 of moving the mobile computer stand from a folded to an unfolded position may include rotating a rotatable member from a base of the support portion about an axis to a user defined angle of separation between the rotatable member and the base. The user defined angle of separation may be within the range of 0° to 90°. In other embodiments, the angle of separation may be any angle within the range of 0° to 85°, and further other embodiments the angle of separation may be any angle within the range of 0° to 75°.

Step 64 of rotating the mobile computer may further include rotating the connection member freely about an axis. The connection member is freely rotatable through an entire 360 degrees of rotation in each direction about the axis and with respect to the support portion, such that the connection member can freely rotate about the axis 30 as little, or as much, as desired by the user. Moreover, the connection member can freely rotate about the axis in a complete 360 degree rotation as many times in succession as desired by the user.

The method 60 may further include steps of moving the mobile computer stand from an unfolded position to a folded position. The method 60 may also include transporting the mobile computer coupled to the mobile computer stand with the stand in the folded position in response to a user holding the handle of the mobile computer stand. The method may include inserting the mobile computer and a portion of the mobile computer stand into a protective sleeve, wherein the handle of the mobile computer stand extends from the sleeve such that a user can hold the handle and transport the mobile computer and mobile computer stand within the protective sleeve.

Additional embodiments of a mobile computer stand are presented in the Appendix, the disclosure of which is incorporated entirely herein by reference.

The embodiments and examples set forth herein were presented in order to best explain the present invention and its practical application and to thereby enable those of ordinary skill in the art to make and use the invention. However, those of ordinary skill in the art will recognize that the foregoing description and examples have been presented for the purposes of illustration and example only. The description as set forth is not intended to be exhaustive or to limit the invention to the precise form disclosed. Many modifications and variations are possible in light of the teachings above without departing from the spirit and scope of the forthcoming claims. For example, a mobile computer may also include e-readers, slate computers, tablet computers and the like.

1. A mobile computer stand comprising:
a support portion comprising a base member, a rotatable member operatively coupled to the base member and an axis; and
a connection member operatively coupled to the support portion, wherein the connection member rotates about the axis in response to rotation of the rotatable member about the axis.

2. The stand of claim 1, wherein a user defined angle is created between the base and the rotatable member in response to rotating the rotatable member about the axis

3. The stand of claim 1, further comprising a mobile computer removably coupled to the connection member.

4. The stand of claim 1, wherein the connection member comprises connectors, wherein the connectors engage and retain a mobile computer in contact with the connection member.

5. The stand of claim 4, wherein the connectors are located at corners of the connection member.

6. The stand of claim 4, wherein the connection member comprises spaces between the connectors, wherein input and output cables are coupled to the mobile computer through the spaces.

7. The stand of claim 1, wherein the support portion comprises a handle.

8. The stand of claim 1, wherein the connection member is operatively coupled to the rotatable member of the support portion, wherein the angle between the base and a front surface of the mobile computer coupled to the connection member is adjusted in response to rotation of the rotatable member.

9. The stand of claim 1, wherein the connection member comprises an axis, wherein the connection member is freely rotatable with respect to the support portion about the axis.

10. The stand of claim 9, wherein the connection member is freely rotatable through an entire 360 degrees of rotation in each direction about the axis.

11. A mobile computer stand comprising:
a support portion comprising a base member, a rotatable member operatively coupled to the base member and an axis; and
a connection member removably and operatively coupled to the support portion, wherein the connection member rotates about the axis in response to rotation of the rotatable member about the axis.

12. The stand of claim 11, further comprising a mobile computer removably coupled to the connection member.

13. The stand of claim 11, wherein the connection member comprises connectors, wherein the connectors engage and retain a mobile computer in contact with the connection member.

14. The stand of claim 13, wherein the connectors comprise a side portion and a lip portion, wherein the side portion engages a portion of a corner of a mobile computer and the lip portion engages a front surface of the mobile computer.

15. The stand of claim 13, wherein the connection member comprises an axis, wherein the connection member is freely rotatable with respect to the support portion about the axis.

16. A method of using a mobile computer stand, the method comprising:
releaseably connecting a mobile computer to a connection member of a mobile computer stand;
moving the mobile computer stand from a folded position to an unfolded position;
supporting a base of the mobile computer stand with a support surface; and
rotating the mobile computer to one of a portrait or a landscape position in response to rotating the connection member to one of a portrait or a landscape position.

17. The method of claim 16, wherein moving the mobile computer stand from a folded position to an unfolded position comprises rotating a rotatable member from a base of the support portion about an axis to a user defined angle of separation between the rotatable member and the base.

18. The method of claim 16, wherein rotating the connection member comprises rotating the connection member freely about an axis.

19. The method of claim 16, further comprising moving the mobile computer stand from an unfolded position to a folded position.

20. The method of claim 19, further comprising transporting the mobile computer coupled to the mobile computer stand with the stand in the folded position in response to a user holding a handle of the mobile computer stand.
